(19) United States
(12) Patent Application Publication
(10) Pub. No.: US 2026/0136656 A1
(43) Pub. Date: May 14, 2026

(54) SEMICONDUCTOR DEVICE

(71) Applicant: SAMSUNG ELECTRONICS CO., LTD, Suwon-si (KR)

(72) Inventors: Hyo Hoon BYEON, Suwon-si (KR); Gyeom KIM, Suwon-si (KR); Seok Hoon KIM, Suwon-si (KR); Pan Kwi PARK, Suwon-si (KR)

(73) Assignee: SAMSUNG ELECTRONICS CO., LTD, Suwon-si (KR)

(21) Appl. No.: 19/229,302

(22) Filed: Jun. 5, 2025

(30) Foreign Application Priority Data
Nov. 8, 2024 (KR) 10-2024-0157916

(51) Int. Cl. H10D 84/85; H10D 84/01

(52) U.S. Cl. CPC H10D 84/852; H10D 84/0167; H10D 84/017; H10D 84/0188

(57) ABSTRACT

A semiconductor device includes a substrate, first and second active patterns, first nanosheets, second nanosheets, a channel isolation layer extending in a first horizontal direction between the first and second active patterns and including first and second sidewalls, the first sidewall being in contact with the first active pattern and the first nanosheets, the second sidewall being in contact with the second active pattern and the second nanosheets; and first and second source/drain regions. The first source/drain region includes a liner layer that is conformal and is in contact with an upper surface of the first active pattern, the first sidewall of the channel isolation layer, and sidewalls of the first nanosheets in the first horizontal direction, and a filling layer disposed on the liner layer, the filling layer not being in contact with the first sidewall of the channel isolation layer.

### CROSS-REFERENCE TO RELATED APPLICATION

This application claims priority from Korean Patent Application No. 10-2024-0157916 filed on Nov. 8, 2024 in the Korean Intellectual Property Office, the contents of which being herein incorporated by reference in its entirety.

### BACKGROUND

The present disclosure relates to a semiconductor device and, more particularly, to a semiconductor device including a Multi-Bridge Channel Field Effect Transistor (MBCFET™).

As one of the scaling techniques to increase the density of integrated circuit devices, multi-gate transistors have been proposed, in which a fin-shaped or nanowire-shaped silicon body is formed on a substrate, and gates are formed on the surface of the silicon body.

Since these multi-gate transistors utilize a three-dimensional channel, the multi-gate transistors are conducive to scaling. Additionally, the current control capability may be improved without increasing the gate length of the multi-gate transistor. Furthermore, the short channel effect (SCE), in which the potential of the channel region is influenced by the drain voltage, may be effectively suppressed.

### SUMMARY

It is an aspect to provide a semiconductor device with enhanced reliability in the source/drain region.

According to an aspect of one or more embodiments, there is provided a semiconductor device comprising a substrate; a first active pattern extending in a first horizontal direction on the substrate; a second active pattern extending in the first horizontal direction on the substrate, the second active pattern spaced apart from the first active pattern in a second horizontal direction different from the first horizontal direction; a first plurality of nanosheets stacked and spaced apart from each other in a vertical direction on the first active pattern; a second plurality of nanosheets stacked and spaced apart from each other in the vertical direction on the second active pattern and spaced apart from the first plurality of nanosheets in the second horizontal direction; a channel isolation layer extending in the first horizontal direction between the first active pattern and the second active pattern, the channel isolation layer comprising a first sidewall in the second horizontal direction and a second sidewall opposite the first sidewall in the second horizontal direction, the first sidewall of the channel isolation layer being in contact with the first active pattern and each of the first plurality of nanosheets, the second sidewall of the channel isolation layer being in contact with the second active pattern and each of the second plurality of nanosheets; a first source/drain region in contact with the first sidewall of the channel isolation layer on the first active pattern; and a second source/drain region in contact with the second sidewall of the channel isolation layer on the second active pattern. The first source/drain region comprises a liner layer that is conformal and is in contact with an upper surface of the first active pattern, the first sidewall of the channel isolation layer, and sidewalls of the first plurality of nanosheets in the first horizontal direction; and a filling layer disposed on the liner layer, the filling layer not being in contact with the first sidewall of the channel isolation layer.

According to another aspect of one or more embodiments, there is provided a semiconductor device comprising a substrate; a first active pattern extending in a first horizontal direction on the substrate; a second active pattern extending in the first horizontal direction on the substrate, the second active pattern spaced apart from the first active pattern in a second horizontal direction different from the first horizontal direction; a channel isolation layer extending in the first horizontal direction between the first active pattern and the second active pattern, sidewalls of the channel isolation layer in the second horizontal direction being in contact with the first active pattern and the second active pattern; a gate electrode extending in the second horizontal direction on the first active pattern and the second active pattern; and a source/drain region disposed on one side of the gate electrode on the first active pattern. The source/drain region comprises a first liner layer that is conformal and is in contact with an upper surface of the first active pattern and a sidewall of the sidewalls of the channel isolation layer in the second horizontal direction; a second liner layer that is formed conformally and is disposed on the first liner layer, the second liner layer being in contact with the first liner layer and being not in contact with the sidewall of the sidewalls of the channel isolation layer in the second horizontal direction; and a filling layer disposed on the second liner layer, the filling layer being in contact with the second liner layer and being not in contact with the sidewall of the sidewalls of the channel isolation layer in the second horizontal direction.

According to yet another aspect of one or more embodiments, there is provided a semiconductor device comprising a substrate; a first active pattern extending in a first horizontal direction on the substrate; a second active pattern extending in the first horizontal direction on the substrate and being spaced apart from the first active pattern in a second horizontal direction different from the first horizontal direction; a first plurality of nanosheets stacked and spaced apart from each other in a vertical direction on the first active pattern; a second plurality of nanosheets stacked and spaced apart from each other in the vertical direction on the second active pattern and being spaced apart from the first plurality of nanosheets in the second horizontal direction; a channel isolation layer extending in the first horizontal direction between the first active pattern and the second active pattern, the channel isolation layer comprising a first sidewall in the second horizontal direction and a second sidewall opposite the first sidewall in the second horizontal direction, the first sidewall of the channel isolation layer being in contact with the first active pattern and each of the first plurality of nanosheets, the second sidewall of the channel isolation layer being in contact with the second active pattern and each of the second plurality of nanosheets; a gate electrode extending in the second horizontal direction on the first active pattern and the second active pattern, the gate electrode surrounding each of the first plurality of nanosheets and each of the second plurality of nanosheets and being isolated in the second horizontal direction by the channel isolation layer; a first source/drain region disposed on one side of the gate electrode on the first active pattern, the first source/drain region being in contact with the first sidewall of the channel isolation layer; a second source/drain region disposed on the one side of the gate electrode on the second active pattern, the second source/drain region being in contact with the second sidewall of the channel isolation layer; a source/drain contact disposed on an upper surface of the first source/drain region and being electrically connected to the first source/drain region; and a silicide layer disposed along an interface between the first source/drain region and the source/drain contact. The first source/drain region comprises a first liner layer that is conformal and is in contact with an upper surface of the first active pattern, the first sidewall of the channel isolation layer, and sidewalls of the first plurality of nanosheets in the first horizontal direction; a second liner layer that is conformal and is disposed on the first liner layer, the second liner layer being in contact with the first liner layer and being not in contact with the first sidewall of the channel isolation layer; and a filling layer disposed on the second liner layer, the filling layer being in contact with the second liner layer and being not in contact with the first sidewall of the channel isolation layer. The silicide layer is in contact with each of the first liner layer, the second liner layer and the filling layer.

### BRIEF DESCRIPTION OF THE DRAWINGS

The above and other aspects will become more apparent by describing in detail exemplary embodiments thereof with reference to the attached drawings, in which:

FIG. 1 is a layout diagram for explaining a semiconductor device according to some exemplary embodiments;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIG. 5 is a plan view taken along line D-D′ in FIG. 2;

FIGS. 6 to 32 are intermediate stage diagrams for explaining semiconductor devices according to some exemplary embodiments;

FIG. 33 is a cross-sectional view for explaining a semiconductor device according to some exemplary embodiments;

FIG. 34 is a plan view taken along line D-D′ of FIG. 33;

FIGS. 35 and 36 are cross-sectional views for explaining a semiconductor device according to some exemplary embodiments;

FIG. 37 is a plan view taken along line D-D′ of FIG. 35; and

FIG. 38 is a cross-sectional view for explaining a semiconductor device according to some exemplary embodiments.

### DETAILED DESCRIPTION

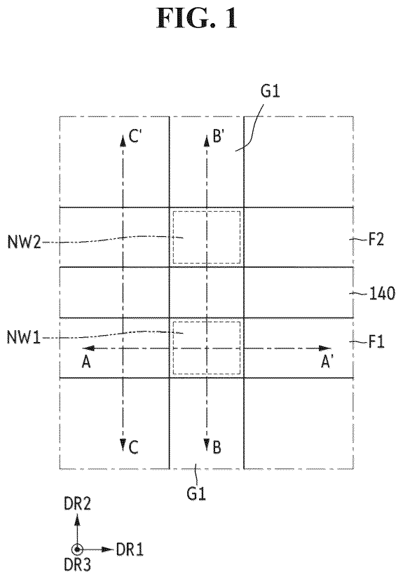

Hereinafter, a semiconductor device according to some exemplary embodiments will be described with reference to FIGS. 1 to 5. As used in this specification, a phrase using the form “at least one of A, B, or C” includes within its scope “only A”, “only B”, “only C”, “A and B”, “A and C”, “B and C” and “A, B, and C.”

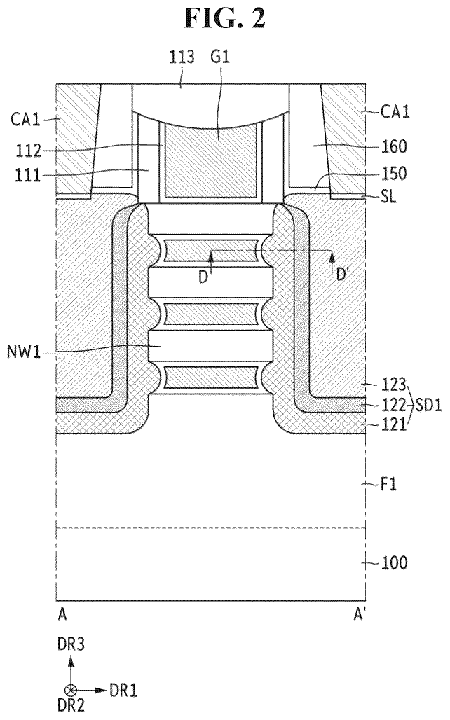

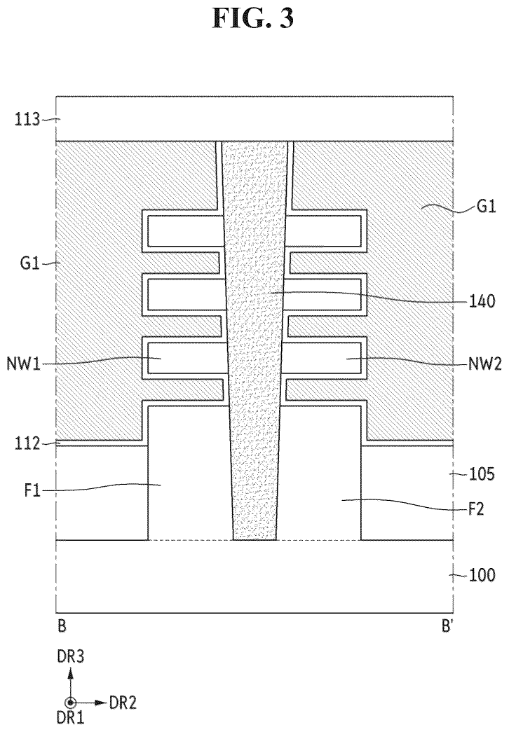

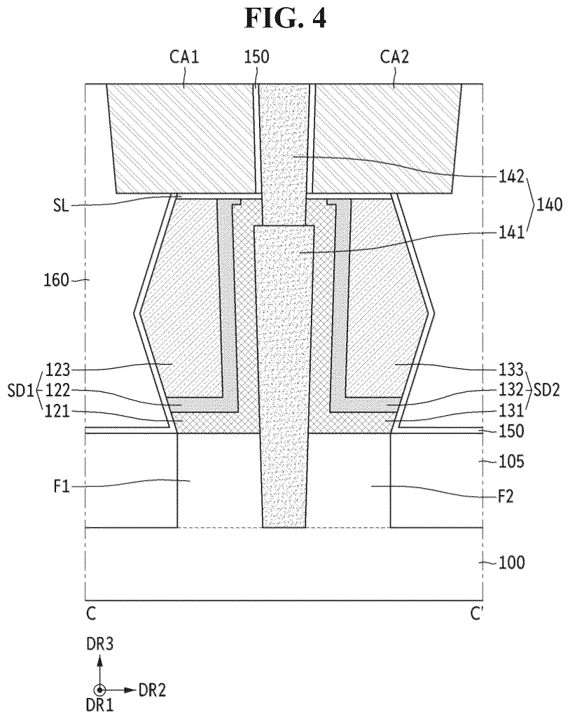

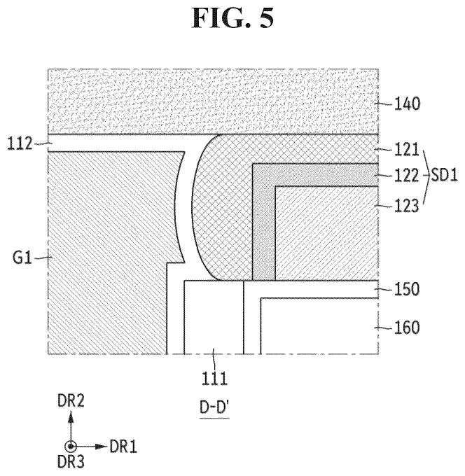

FIG. 1 is a schematic layout diagram for explaining a semiconductor device according to some exemplary embodiments. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1. FIG. 5 is a plan view taken along line D-D′ in FIG. 2.

Referring to FIG. 1 to FIG. 5, the semiconductor device according to some exemplary embodiments includes a substrate 100, a first active pattern F1, a second active pattern F2, a field insulating layer 105, a first plurality of nanosheets NW1, a second plurality of nanosheets NW2, gate electrodes G1, a gate spacer 111, a gate insulating layer 112, a capping pattern 113, a first source/drain region SD1, a second source/drain region SD2, a channel isolation layer 140, an etching stop layer 150, an interlayer insulating layer 160, a first source/drain contact CA1, a second source/drain contact CA2, and a silicide layer SL.

In some exemplary embodiments, the substrate 100 may be a silicon substrate or an silicon-on-insulator (SOI) substrate. In some exemplary embodiments, the substrate 100 may include silicon germanium, silicon germanium-on-insulator (SGOI), indium antimonide, lead telluride compounds, indium arsenide, indium phosphide, gallium arsenide, and/or gallium antimonide, but exemplary embodiments are not limited thereto.

The first horizontal direction DR1 and a second horizontal direction DR2 may each be defined as a direction parallel to an upper surface of the substrate 100. The second horizontal direction DR2 may be defined as a direction different from the first horizontal direction DR1. A vertical direction DR3 may be defined as a direction perpendicular to both the first horizontal direction DR1 and the second horizontal direction DR2. In other words, the vertical direction DR3 may be defined as a direction perpendicular to the upper surface of the substrate 100.

Each of the first active pattern F1 and the second active pattern F2 may extend in the first horizontal direction DR1 on the upper surface of the substrate 100. The second active pattern F2 may be spaced apart from the first active pattern F1 in the second horizontal direction DR2. Each of the first and second active patterns F1, F2 may protrude from the upper surface of the substrate 100 in the vertical direction DR3 (see, e.g., FIG. 2). For example, each of the first and second active patterns F1, F2 may be part of the substrate 100 or may include an epitaxial layer grown from the substrate 100. For example, the first active pattern F1 and the second active pattern F2 may be isolated in the second horizontal direction DR2 by the channel isolation layer 140 described later.

The field insulating layer 105 may be disposed on the upper surface of the substrate 100. The field insulating layer 105 may surround the sidewalls of each of the first and second active patterns F1, F2. For example, in an exemplary embodiment, the upper surface of each of the first and second active patterns F1, F2 may protrude further in the vertical direction DR3 than the upper surface of the field insulating layer 105. However, exemplary embodiments are not limited to this. In some exemplary embodiments, the upper surface of each of the first and second active patterns F1, F2 may be formed on the same plane as the upper surface of the field insulating layer 105. The field insulating layer 105 may include, for example, an oxide layer, a nitride layer, an oxynitride layer, or a combination thereof.

The first plurality of nanosheets NW1 may be disposed on the first active pattern F1. The first plurality of nanosheets NW1 may include multiple nanosheets stacked and spaced apart from each other in the vertical direction DR3 on the first active pattern F1. The second plurality of nanosheets NW2 may be disposed on the second active pattern F2. The second plurality of nanosheets NW2 may include multiple nanosheets stacked and spaced apart from each other in the vertical direction DR3 on the second active pattern F2. The second plurality of nanosheets NW2 may be spaced apart from the first plurality of nanosheets NW1 in the second horizontal direction DR2.

In FIGS. 2 and 3, it is shown that each of the first plurality of nanosheets NW1 and the second plurality of nanosheets NW2 includes three nanosheets stacked and spaced apart from each other in the vertical direction DR3, but exemplary embodiments are not limited to this. In some exemplary embodiments, each of the first plurality of nanosheets NW1 and the second plurality of nanosheets NW2 may include four or more nanosheets stacked and spaced apart from each other in the vertical direction DR3. For example, the first plurality of nanosheets NW1 and the second plurality of nanosheets NW2 may be isolated in the second horizontal direction DR2 by the channel isolation layer 140 described later. For example, in an exemplary embodiment, each of the first plurality of nanosheets NW1 and the second plurality of nanosheets NW2 may include silicon (Si).

The gate electrodes G1 may extend in the second horizontal direction DR2 on the field insulating layer 105 and each of the first and second active patterns F1 and F2. The gate electrodes G1 may surround each of the first plurality of nanosheets NW1 and the second plurality of nanosheets NW2. For example, the gate electrodes G1 may be isolated from each other in the second horizontal direction DR2 by the channel isolation layer 140 described below. However, exemplary embodiments are not limited thereto.

In some exemplary embodiments, the gate electrodes G1 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), or vanadium (V) or any combinations thereof. The gate electrodes G1 may include conductive metal oxides, conductive metal oxynitrides, etc. and/or may include oxidized forms of the aforementioned materials.

The gate spacer 111 may be disposed on both sidewalls of the gate electrodes G1 in the first horizontal direction DR1. For example, the gate spacer 111 may extend in the second horizontal direction DR2 on the upper surface of the uppermost nanosheets of each of the first and second plurality of nanosheets NW1, NW2 and on the field insulating layer 105. For example, the gate spacer 111 may include at least one of silicon nitride (SiN), silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon borocarbide (SiBC), silicon boron carbonitride (SiBCN), or silicon oxycarbide (SiOC), or combinations thereof. However, exemplary embodiments are not limited thereto.

The channel isolation layer 140 may extend in the first horizontal direction DR1 between the first active pattern F1 and the second active pattern F2. For example, the channel isolation layer 140 may isolate the first active pattern F1 and the second active pattern F2 in the second horizontal direction DR2. In some exemplary embodiments, the channel isolation layer 140 may isolate the first plurality of nanosheets NW1 and the second plurality of nanosheets NW2 in the second horizontal direction DR2. In some exemplary embodiments, the channel isolation layer 140 may isolate the gate electrodes G1 in the second horizontal direction DR2. For example, the channel isolation layer 140 may include a first sidewall and a second sidewall opposite the first sidewall in the second horizontal direction DR2. For example, the first sidewall of the channel isolation layer 140 may be in contact with the first active pattern F1 and each of the first plurality of nanosheets NW1. The second sidewall of the channel isolation layer 140 may be in contact with the second active pattern F2 and each of the second plurality of nanosheets NW2.

In some exemplary embodiments, the bottom surface of the channel isolation layer 140 may be in contact with the upper surface of the substrate 100. For example, the bottom surface of the channel isolation layer 140 may be formed on the same plane as the bottom surface of each of the first and second active patterns F1, F2. However, exemplary embodiments are not limited thereto. For example, the upper surface of the channel isolation layer 140 disposed between the gate electrodes G1 may be formed on the same plane as the upper surface of the gate electrodes G1. However, exemplary embodiments are not limited thereto. In some exemplary embodiments, the upper surface of the channel isolation layer 140 disposed between the gate electrodes G1 may be formed lower than the upper surface of the gate electrodes G1. For example, the upper surface of the channel isolation layer 140 between the gate electrodes G1 may be formed higher than the upper surface of the uppermost nanosheets of each of the first and second plurality of nanosheets NW1, NW2. For example, in an exemplary embodiment, the channel isolation layer 140 may include silicon nitride (SiN). However, exemplary embodiments are not limited thereto. In some exemplary embodiments, the channel isolation layer 140 may include silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon borocarbide (SiBC), silicon boron carbonitride (SiBCN), and/or silicon oxycarbide (SiOC).

In some exemplary embodiments, the channel isolation layer 140 may include a first portion 141 and a second portion 142 (see, e.g., FIG. 4). In some exemplary embodiments, the upper surface of the first portion 141 of the channel isolation layer 140 disposed between the first source/drain region SD1 and the second source/drain region SD2 described later, may be formed lower than the upper surface of the channel isolation layer 140 disposed between the gate electrodes G1. In some exemplary embodiments, the second portion 142 of the channel isolation layer 140 may be disposed on the upper surface of the first portion 141 of the channel isolation layer 140. In some exemplary embodiments, the second portion 142 of the channel isolation layer 140 may be disposed on the upper surface of the first portion 141 of the channel isolation layer 140 disposed between the first source/drain region SD1 and the second source/drain region SD2 (see, e.g., FIG. 4). However, in an exemplary embodiment, the second portion 142 of the channel isolation layer 140 may not disposed on the upper surface of the channel isolation layer 140 disposed between the gate electrodes G1 (see, e.g., FIG. 3). The bottom surface of the second portion 142 of the channel isolation layer 140 may be in contact with the upper surface of the first portion 141 of the channel isolation layer 140.

In some exemplary embodiments, the upper surface of the second portion 142 of the channel isolation layer 140 may be formed higher than the upper surface of the channel isolation layer 140 disposed between the gate electrodes G1. In other words, the uppermost surface of the channel isolation layer 140 may be defined as the upper surface of the second portion 142 of the channel isolation layer 140. In some exemplary embodiments, a width of the upper surface of the first portion 141 of the channel isolation layer 140 in the second horizontal direction DR2 may be greater than a width of the bottom surface of the first portion 141 of the channel isolation layer 140 in the second horizontal direction DR2. In some exemplary embodiments, a width of the upper surface of the second part 142 of the channel isolation layer 140 in the second horizontal direction DR2 may be greater than a width of the bottom surface of the second part 142 of the channel isolation layer 140 in the second horizontal direction DR2.

In some exemplary embodiments, the width of the upper surface of the first portion 141 of the channel isolation layer 140 in the second horizontal direction DR2 may be greater than the width of the bottom surface of the second portion 142 of the channel isolation layer 140 in the second horizontal direction DR2. However, exemplary embodiments are not limited thereto. In some exemplary embodiments, the width of the upper surface of the first portion 141 of the channel isolation layer 140 in the second horizontal direction DR2 may be equal to the width of the bottom surface of the second portion 142 of the channel isolation layer 140 in the second horizontal direction DR2. In some exemplary embodiments, the width of the upper surface of the first portion 141 of the channel isolation layer 140 in the second horizontal direction DR2 may be smaller than the width of the bottom surface of the second portion 142 of the channel isolation layer 140 in the second horizontal direction DR2. In some exemplary embodiments, the first portion 141 and the second portion 142 of the channel isolation layer 140 may contain the same material. However, exemplary embodiments are not limited thereto.

The first source/drain region SD1 may be disposed on at least one side of the gate electrodes G1 on the first active pattern F1. In some exemplary embodiments, the first source/drain region SD1 may be disposed on both sides of the gate electrodes G1 on the first active pattern F1. The first source/drain region SD1 may be in contact with both sidewalls of the first plurality of nanosheets NW1 in the first horizontal direction DR1. For example, at least a portion of the first source/drain region SD1 may be formed convexly toward the gate electrodes G1 between the upper surface of the first active pattern F1 and the bottom surface of the lowermost nanosheet of the first plurality of nanosheets NW1. In some exemplary embodiments, at least a portion of the first source/drain region SD1 may be formed convexly toward the gate electrodes G1 between adjacent ones of the first plurality of nanosheets NW1.

The second source/drain region SD2 may be disposed on at least one side of the gate electrodes G1 on the second active pattern F2. In some exemplary embodiments, the second source/drain region SD2 may be disposed on both sides of the gate electrodes G1 on the second active pattern F2. The second source/drain region SD2 may be in contact with both sidewalls of the second plurality of nanosheets NW2 in the first horizontal direction DR1. The second source/drain region SD2 may be spaced apart from the first source/drain region SD1 in the second horizontal direction DR2. In some exemplary embodiments, the first source/drain region SD1 and the second source/drain region SD2 may be isolated in the second horizontal direction DR2 by the channel isolation layer 140. In some exemplary embodiments, the first source/drain region SD1 may be in contact with the first sidewall of the channel isolation layer 140 in the second horizontal direction DR2. The second source/drain region SD2 may be in contact with the second sidewall of the channel isolation layer 140 in the second horizontal direction DR2.

In some exemplary embodiments, the bottom surface of the first source/drain region SD1 may be in contact with the first active pattern F1. The bottom surface of the second source/drain region SD2 may be in contact with the second active pattern F2. In some exemplary embodiments, the upper surface of the first portion 141 of the channel isolation layer 140 may be formed lower than the upper surface of each of the first and second source/drain regions SD1, SD2. In some exemplary embodiments, the upper surface of the second portion 142 of the channel isolation layer 140 may be formed higher than the upper surface of each of the first and second source/drain regions SD1, SD2. In other words, the uppermost surface of the channel isolation layer 140 may be formed higher than the upper surface of each of the first and second source/drain regions SD1, SD2.

In some exemplary embodiments, the first source/drain region SD1 may include liner layers 121, 122 and a filling layer 123. In some exemplary embodiments, the liner layers 121, 122 of the first source/drain region SD1, taken together, may be in contact with the upper surface of the first active pattern F1, the first sidewall of the channel isolation layer 140 in the second horizontal direction DR2, and both sidewalls of the first plurality of nanosheets NW1 in the first horizontal direction DR1, respectively. In some exemplary embodiments, the liner layers 121, 122 of the first source/drain region SD1 may be formed conformally. In some exemplary embodiments, the filling layer 123 of the first source/drain region SD1 may be disposed on the liner layers 121, 122 of the first source/drain region SD1. The filling layer 123 of the first source/drain region SD1 may be in contact with the liner layers 121, 122 of the first source/drain region SD1, taken together. In some exemplary embodiments, the filling layer 123 of the first source/drain region SD1 may not be in contact with the upper surface of the first active pattern F1, the first sidewall of the channel isolation layer 140 in the second horizontal direction DR2, and both sidewalls of the first plurality of nanosheets NW1 in the first horizontal direction DR1, respectively.

In some exemplary embodiments, the liner layers 121, 122 of the first source/drain region SD1 may include the first liner layer 121 and the second liner layer 122. In some exemplary embodiments, the first liner layer 121 of the first source/drain region SD1 may be in contact with the upper surface of the first active pattern F1, the first sidewall of the channel isolation layer 140 in the second horizontal direction DR2, and both sidewalls of the first plurality of nanosheets NW1 in the first horizontal direction DR1, respectively. In some exemplary embodiments, the first liner layer 121 of the first source/drain region SD1 may be formed conformally.

In some exemplary embodiments, the second liner layer 122 of the first source/drain region SD1 may be disposed between the first liner layer 121 of the first source/drain region SD1 and the filling layer 123 of the first source/drain region SD1. The second liner layer 122 of the first source/drain region SD1 may be in contact with the first liner layer 121 of the first source/drain region SD1 and the filling layer 123 of the first source/drain region SD1, respectively. In some exemplary embodiments, the second liner layer 122 of the first source/drain region SD1 may be conformally formed. In some exemplary embodiments, the second liner layer 122 of the first source/drain region SD1 may not be in contact with the upper surface of the first active pattern F1, the first sidewall of the channel isolation layer 140 in the second horizontal direction DR2, and both sidewalls of the first plurality of nanosheets NW1 in the first horizontal direction DR1, respectively.

In some exemplary embodiments, the second source/drain region SD2 may include a first liner layer 131, a second liner layer 132, and a filling layer 133. In some exemplary embodiments, the first liner layer 131 of the second source/drain region SD2 may be in contact with the upper surface of the second active pattern F2, the second sidewall of the channel isolation layer 140 in the second horizontal direction DR2, and both sidewalls of the second plurality of nanosheets NW2 in the first horizontal direction DR1, respectively. In some exemplary embodiments, the second liner layer 132 of the second source/drain region SD2 may be disposed on the first liner layer 131 of the second source/drain region SD2. The filling layer 133 of the second source/drain region SD2 may be disposed on the second liner layer 132 of the second source/drain region SD2. In some exemplary embodiments, the second source/drain region SD2 may be disposed symmetrically with respect to the first source/drain region SD1 based on the channel isolation layer 140. In some exemplary embodiments, the first and second liner layers 131, 132 and the filling layer 133 may be similar to the first and second liner layers 121, 122 and the filling layer 123 described above in terms of structure, material, and configurations. Therefore, detailed explanations of each of the first liner layer 131, the second liner layer 132, and the filling layer 133 of the second source/drain region SD2 will be omitted for conciseness.

In some exemplary embodiments, each of the first and second source/drain regions SD1, SD2 may be the source/drain region of a PMOS transistor. In this case, each of the first and second source/drain regions SD1, SD2 may include undoped silicon germanium (SiGe). For example, each of the first and second source/drain regions SD1, SD2 may include silicon germanium (SiGe) doped with one or more of boron (B), gallium (Ga), or carbon (C). For example, the concentration of germanium (Ge) contained in the filling layer 123 of the first source/drain region SD1 and the filling layer 133 of the second source/drain region SD2 may be greater than the concentration of germanium (Ge) contained in the second liner layer 122 of the first source/drain region SD1 and the second liner layer 132 of the second source/drain region SD2, respectively. In some exemplary embodiments, the concentration of germanium (Ge) contained in each of the second liner layer 122 of the first source/drain region SD1 and the second liner layer 132 of the second source/drain region SD2 may be greater than the concentration of germanium (Ge) contained in each of the first liner layer 121 of the first source/drain region SD1 and the first liner layer 131 of the second source/drain region SD2.

In some exemplary embodiments, the concentration of germanium (Ge) contained in the first liner layer 121 of the first source/drain region SD1 and the first liner layer 131 of the second source/drain region SD2 may each range from 0 at % (atomic %) to 5 at %. In some exemplary embodiments, the concentration of germanium (Ge) contained in the second liner layer 122 of the first source/drain region SD1 and the second liner layer 132 of the second source/drain region SD2 may each range from 5 at % to 20 at %. In some exemplary embodiments, the concentration of germanium (Ge) contained in the filling layer 123 of the first source/drain region SD1 and the filling layer 133 of the second source/drain region SD2 may each range from 20 at % to 60 at %.

In some exemplary embodiments, each of the first and second source/drain regions SD1, SD2 may be a source/drain region of an NMOS transistor. In this case, each of the first and second source/drain regions SD1, SD2 may include silicon (Si) doped with one or more of phosphorus (P), arsenic (As), antimony (Sb), or carbon (C). The concentration of impurities doped in each of the filling layer 123 of the first source/drain region SD1 and the filling layer 133 of the second source/drain region SD2 may be greater than the concentration of impurities doped in each of the second liner layer 122 of the first source/drain region SD1 and the second liner layer 132 of the second source/drain region SD2. In some exemplary embodiments, the concentration of impurities doped in each of the second liner layer 122 of the first source/drain region SD1 and the second liner layer 132 of the second source/drain region SD2 may be greater than the concentration of impurities doped in each of the first liner layer 121 of the first source/drain region SD1 and the first liner layer 131 of the second source/drain region SD2.

The gate insulating layer 112 may be disposed between the gate electrodes G1 and the first active pattern F1. The gate insulating layer 112 may be disposed between the gate electrodes G1 and the second active pattern F2. The gate insulating layer 112 may be disposed between the gate electrodes G1 and the field insulating layer 105. The gate insulating layer 112 may be disposed between the gate electrodes G1 and the first plurality of nanosheets NW1. The gate insulating layer 112 may be disposed between the gate electrodes G1 and the second plurality of nanosheets NW2. The gate insulating layer 112 may be disposed between the gate electrodes G1 and the channel isolation layer 140. The gate insulating layer 112 may be disposed between the gate electrodes G1 and the gate spacer 111. The gate insulating layer 112 may be disposed between the gate electrodes G1 and the first source/drain region SD1. The gate insulating layer 112 may be disposed between the gate electrodes G1 and the second source/drain region SD2. In some exemplary embodiments, the gate insulating layer 112 may be in contact with each of the first and second source/drain regions SD1, SD2.

The gate insulating layer 112 may include at least one of silicon oxide, silicon oxynitride, silicon nitride, or a high-k dielectric material having a dielectric constant greater than that of silicon oxide. High-k dielectric materials may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate.

The semiconductor device according to some exemplary embodiments may include an Negative Capacitance (NC) FET utilizing a negative capacitor. NC (, the gate insulating layer 112 may include a ferroelectric material layer having ferroelectric properties and a paraelectric material layer having paraelectric properties.

The ferroelectric material layer may exhibit negative capacitance, while the paraelectric material layer may exhibit positive capacitance. For example, when two or more capacitors are connected in series and each of their capacitances has a positive value, the overall capacitance decreases relative to the capacitance of each individual capacitor. On the other hand, if the capacitances of at least one of the two or more capacitors connected in series has a negative value, the overall capacitance may be greater than the absolute value of each individual capacitance while still being positive.

When the ferroelectric material layer with negative capacitance and the paraelectric material layer with positive capacitance are connected in series, the overall capacitance value of the ferroelectric material layer and the paraelectric material layer connected in series may increase. By utilizing the increase in overall capacitance value, the transistor including the ferroelectric material layer may have a subthreshold swing (SS) of less than 60 mV/decade at room temperature.

The ferroelectric material layer may have ferroelectric properties. In some exemplary embodiments, the ferroelectric material layer may include, for example, at least one of hafnium oxide, hafnium zirconium oxide, barium strontium titanium oxide, barium titanium oxide, or lead zirconium titanium oxide. In some exemplary embodiments, hafnium zirconium oxide may be a material in which zirconium (Zr) is doped into hafnium oxide. In some exemplary embodiments, hafnium zirconium oxide may be a compound of hafnium (Hf) and zirconium (Zr) with oxygen (O).

The ferroelectric material layer may further include a doped dopant. In some exemplary embodiments, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). Depending on which ferroelectric material the ferroelectric material layer contains, the type of dopant contained in the ferroelectric material layer may vary.

If the ferroelectric material layer includes hafnium oxide, the dopant included in the ferroelectric material layer may include, for example, at least one of gadolinium (Gd), silicon (Si), zirconium (Zr), aluminum (Al), or yttrium (Y).

If the dopant is aluminum (Al), the ferroelectric material layer may contain aluminum in a concentration of about 3 to 8 at % (atomic %). Here, the ratio of the dopant may be a ratio of aluminum relative to the sum of hafnium and aluminum.

If the dopant is silicon (Si), the ferroelectric material layer may contain 2 to 10 at % of silicon. If the dopant is yttrium (Y), the ferroelectric material layer may contain 2 to 10 at % of yttrium. If the dopant is gadolinium (Gd), the ferroelectric material layer may contain 1 to 7 at % of gadolinium. If the dopant is zirconium (Zr), the ferroelectric material layer may contain 50 to 80 at % of zirconium.

The paraelectric material layer may have paraelectric properties. The paraelectric material layer may include, for example, at least one of silicon oxide or metal oxides with a high-k dielectric constant. The metal oxides contained in the paraelectric material layer may include, for example, at least one of hafnium oxide, zirconium oxide, or aluminum oxide, but exemplary embodiments are not limited to these.

The ferroelectric material layer and the paraelectric material layer may include the same material. While the ferroelectric material layer may have ferroelectric properties, the paraelectric material layer may not have ferroelectric properties. For example, if both the ferroelectric material layer and the paraelectric material layer contain hafnium oxide, the crystal structure of the hafnium oxide included in the ferroelectric material layer is different from the crystal structure of the hafnium oxide included in the paraelectric material layer.

The ferroelectric material layer may have a thickness having ferroelectric properties. In some exemplary embodiments, the thickness of the ferroelectric material layer may range from 0.5 to 10 nm, but exemplary embodiments are not limited thereto. Since a critical thickness for exhibiting ferroelectric properties may vary depending on the ferroelectric material, the thickness of the ferroelectric material layer may differ based on the specific ferroelectric material used.

In some exemplary embodiments, the gate insulating layer 112 may include a single ferroelectric material layer. In some exemplary embodiments, the gate insulating layer 112 may include multiple ferroelectric material layers spaced apart from each other. In some exemplary embodiments, the gate insulating layer 112 may have a stacked structure in which multiple ferroelectric material layers and multiple paraelectric material layers are alternately stacked.

The etching stop layer 150 may be disposed on the sidewalls of the gate spacer 111 in the first horizontal direction DR1. The etching stop layer 150 may be disposed on the upper surface of the field insulating layer 105. The etching stop layer 150 may be disposed on the sidewalls of each of the first and second source/drain regions SD1, /SD2 in the second horizontal direction DR2. In some exemplary embodiments, the etching stop layer 150 may be disposed on both sidewalls of the second portion 142 of the channel isolation layer 140 in the second horizontal direction DR2, on the upper surface of each of the first and second source/drain regions SD1, SD2, but exemplary embodiments are not limited thereto. In some exemplary embodiments, the etching stop layer 150 may be conformally formed. In some exemplary embodiments, the etching stop layer 150 may include at least one of aluminum oxide, aluminum nitride, hafnium oxide, zirconium oxide, silicon oxide, silicon nitride, silicon oxynitride, or low-k dielectric materials.

The capping pattern 113 may extend in the second horizontal direction DR2 on the upper surface of each of the gate spacer 111, the gate insulating layer 112, and the gate electrode G1. The capping pattern 113 may be in contact with the upper surface of each of the gate spacer 111, the gate insulating layer 112, and the gate electrode G1. In some exemplary embodiments, the bottom surface of the capping pattern 113 may be in contact with the upper surface of the first portion 141 of the channel isolation layer 140. In some exemplary embodiments, the bottom surface of the capping pattern 113 may be in contact with an etching stop layer 150. However, exemplary embodiments are not limited thereto. In some exemplary embodiments, the capping pattern 113 may include silicon nitride (SiN), silicon oxynitride (SiON), silicon oxide (SiO₂), silicon carbonitride (SiCN), silicon oxycarbonitride (SiOCN), or combinations thereof. However, exemplary embodiments are not limited thereto.

The interlayer insulating layer 160 may be disposed on the etching stop layer 150. The interlayer insulating layer 160 may cover each of the first and second source/drain regions SD1, SD2 on the field insulating layer 105. In some exemplary embodiments, the upper surface of the interlayer insulating layer 160 may be formed on the same plane as the upper surface of the capping pattern 113. In some exemplary embodiments, the interlayer insulating layer 160 may include at least one of silicon oxide, silicon nitride, silicon oxynitride, or low-k dielectric materials.

Each of the first and second source/drain contacts CA1, CA2 may be disposed inside the interlayer insulating layer 160. For example, the first source/drain contact CA1 may be disposed on the upper surface of the first source/drain region SD1. The first source/drain contact CA1 may be electrically connected to the first source/drain region SD1. In some exemplary embodiments, the second source/drain contact CA2 may be disposed on the upper surface of the second source/drain region SD2. The second source/drain contact CA2 may be spaced apart from the first source/drain contact CA1 in the second horizontal direction DR2. The second source/drain contact CA2 may be electrically connected to the second source/drain region SD2. In some exemplary embodiments, the first and second source/drain contacts CA1, CA2 may be isolated in the second horizontal direction DR2 by the second portion 142 of the channel isolation layer 140. Each of the first and second source/drain contacts CA1, CA2 may include a conductive material.

The silicide layer SL may be disposed along the interface between the first source/drain region SD1 and the first source/drain contact CA1. The silicide layer SL may also be disposed along the interface between the second source/drain region SD2 and the second source/drain contact CA2. In some exemplary embodiments, the silicide layer SL may be in contact with the upper surface of each of the first liner layer 121, the second liner layer 122, and the filling layer 123 of the first source/drain region SD1. The silicide layer SL may also be in contact with the upper surface of each of the first liner layer 131, the second liner layer 132 and the filling layer 133 of the second source/drain region SD2. In some exemplary embodiments, the silicide layer SL may include a metal silicide material.

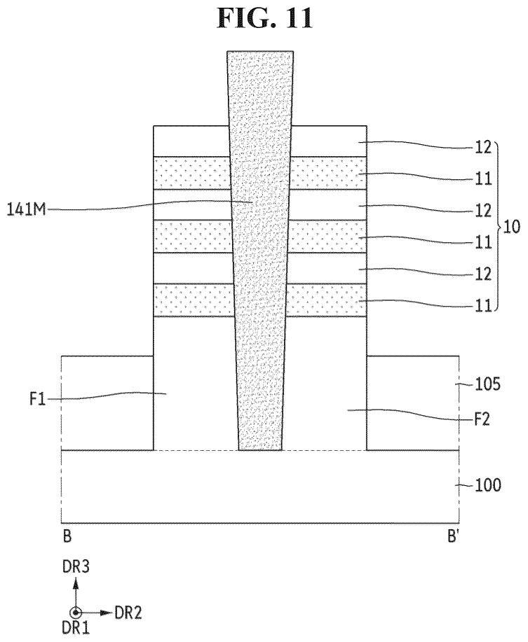

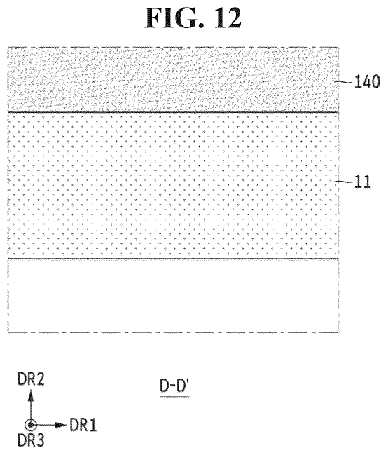

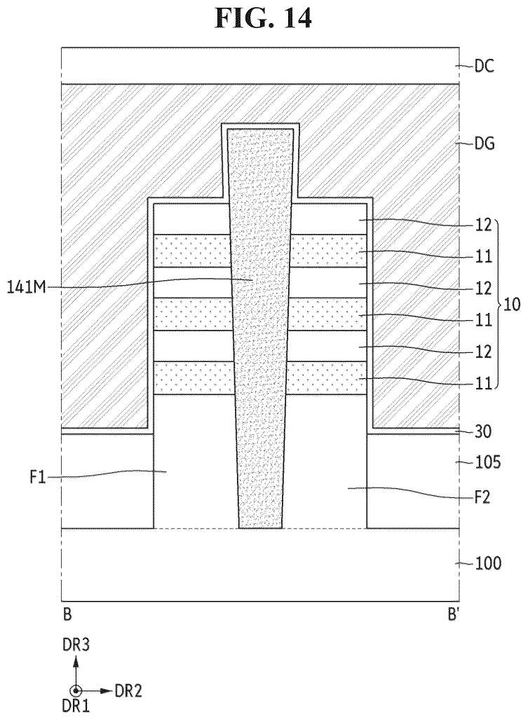

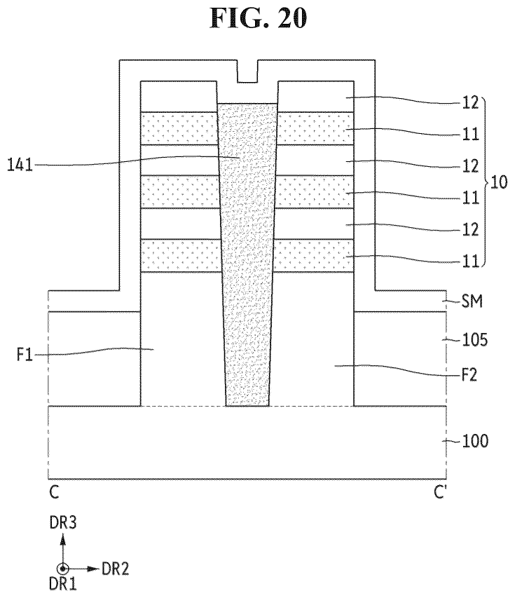

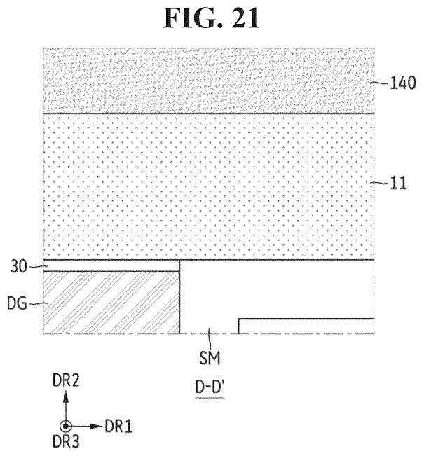

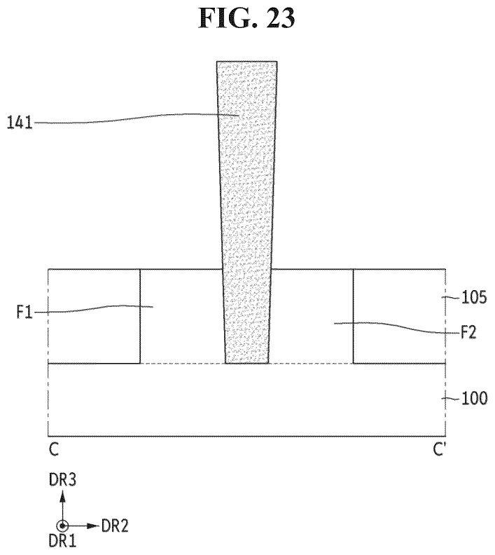

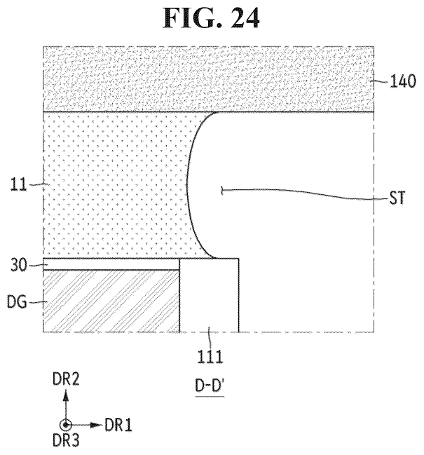

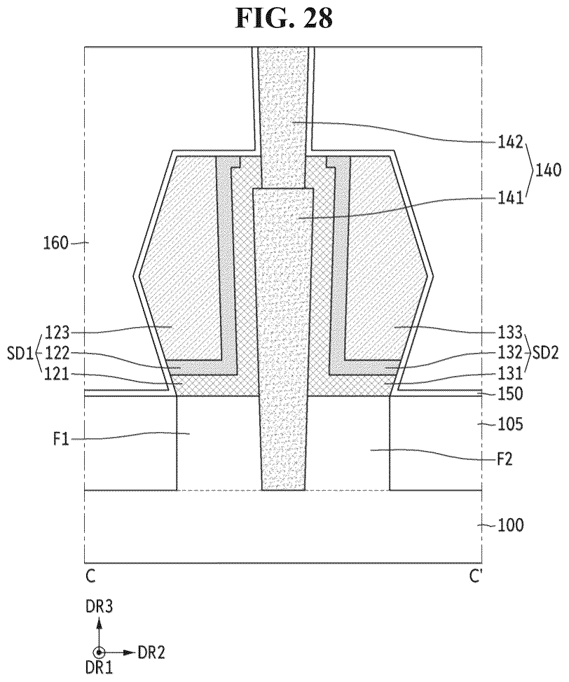

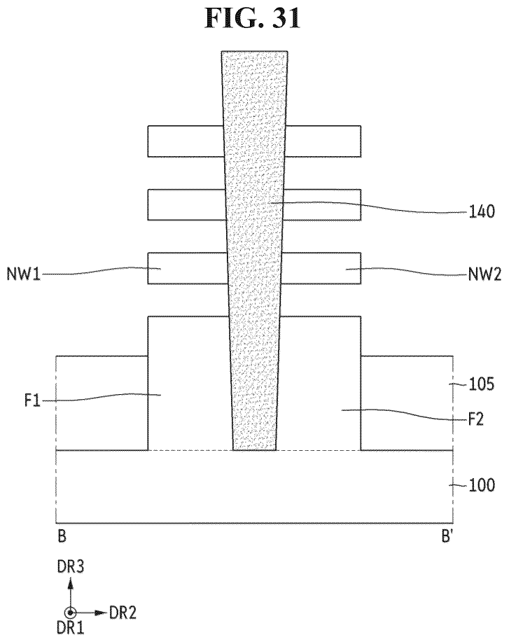

Hereinafter, a method for fabricating the semiconductor device according to some exemplary embodiments is described with reference to FIGS. 2 to 32.

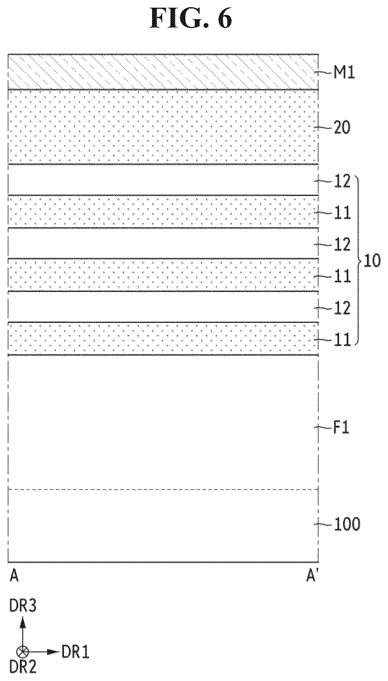

FIGS. 6 to 32 are intermediate stage diagrams for explaining the semiconductor device according to some exemplary embodiments.

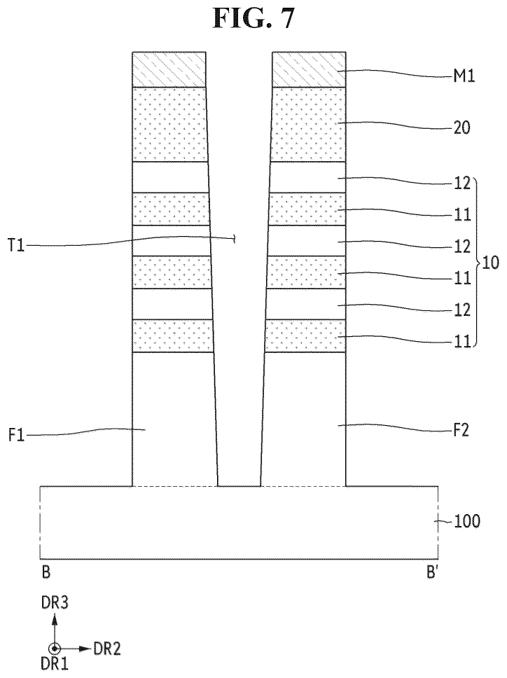

Referring to FIGS. 6 and 7, a stacked structure 10 may be formed on the substrate 100. The stacked structure 10 may include a first semiconductor layer 11 and a second semiconductor layer 12 alternately stacked on the upper surface of the substrate 100. For example, the first semiconductor layer 11 may be formed at the lowermost portion of the stacked structure 10, and the second semiconductor layer 12 may be formed at the uppermost portion of the stacked structure 10. The first semiconductor layer 11 may include, for example, silicon germanium (SiGe). The second semiconductor layer 12 may include, for example, silicon (Si). Subsequently, a third semiconductor layer 20 may be formed on the upper surface of the stacked structure 10. For example, the thickness of the third semiconductor layer 20 in the vertical direction DR3 may be greater than the thickness of each of the first semiconductor layer 11 and the second semiconductor layer 12 in the vertical direction DR3. For example, the third semiconductor layer 20 may include silicon germanium (SiGe).

Subsequently, a mask pattern M1 may be formed on the upper surface of the third semiconductor layer 20. Then, using the mask pattern M1 as a mask, the third semiconductor layer 20 and the stacked structure 10 may be etched. While the third semiconductor layer 20 and the stacked structure 10 are being etched, a portion of the substrate 100 may also be etched. Through the etching process, the first active pattern F1 and the second active pattern F2 may be defined beneath the stacked structure 10 on the upper surface of the substrate 100. For example, each of the first and second active patterns F1, F2 may extend in the first horizontal direction DR1. The second active pattern F2 may be spaced apart from the first active pattern F1 in the second horizontal direction DR2. The stacked structure 10 formed on the second active pattern F2 may be spaced apart from the stacked structure 10 formed on the first active pattern F1 in the second horizontal direction DR2. For example, the region between the first active pattern F1 and the second active pattern F2 may be defined as an isolation trench T1.

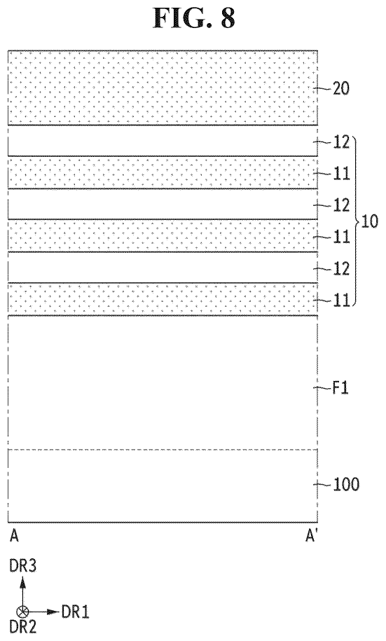

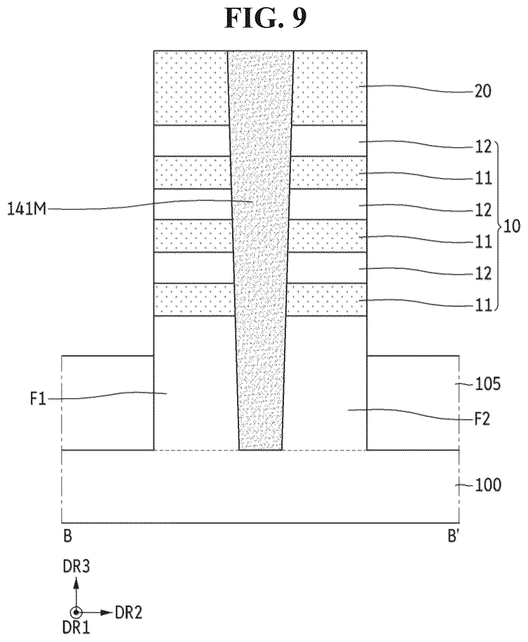

. Referring to FIGS. 8 and 9, an isolation material layer 141M may be formed inside the isolation trench T1 (see FIG. 7). For example, the upper surface of the isolation material layer 141M may be formed on the same plane as the upper surface of the third semiconductor layer 20. For example, the mask pattern M1 (see FIGS. 6 and 7) may be etched while the isolation material layer 141M is being formed. The isolation material layer 141M may contain the same material as the first portion 141 of the channel isolation layer 140 shown in FIG. 4. Subsequently, the field insulating layer 105 may be formed to surround the sidewall of each of the first and second active patterns F1, F2 on the upper surface of the substrate 100.

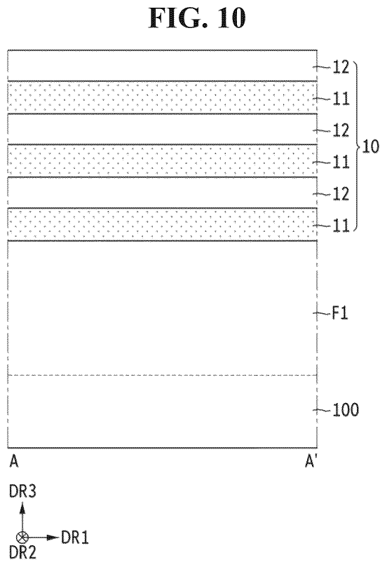

Referring to FIG. 10 to FIG. 12, the third semiconductor layer 20 (see FIG. 8 and FIG. 9) may be etched. Through the etching process, portions of both sidewalls of the isolation material layer 141M in the second horizontal direction DR2 may be exposed.

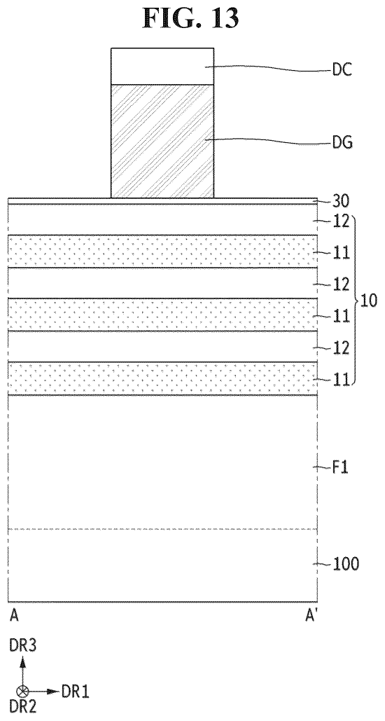

Referring to FIGS. 13 to 15, a pad oxide layer 30 may be formed to cover the upper surface of the field insulating layer 105, the sidewalls of each of the exposed first and second active patterns F1, F2, the sidewalls and upper surface of the stacked structure 10, and the sidewalls and upper surface of the exposed isolation material layer 141M. The pad oxide layer 30 may include, for example, silicon oxide (SiO₂). Then, a dummy gate DG and a dummy capping pattern DC extending in the second horizontal direction DR2 may be formed on the pad oxide layer 30. The dummy capping pattern DC may be formed on the upper surface of the dummy gate DG.

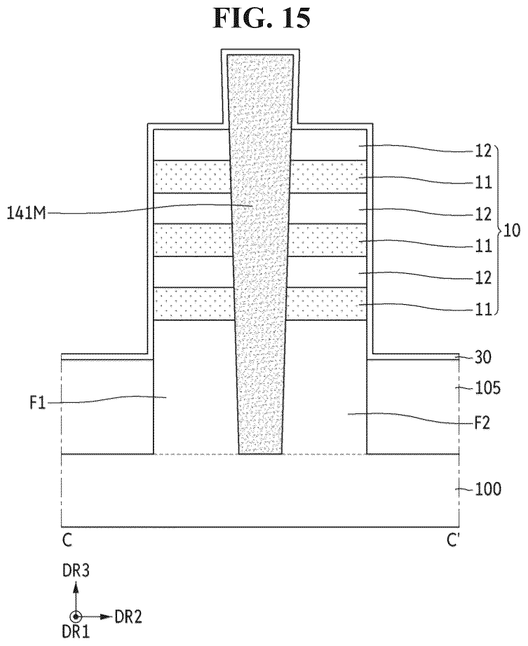

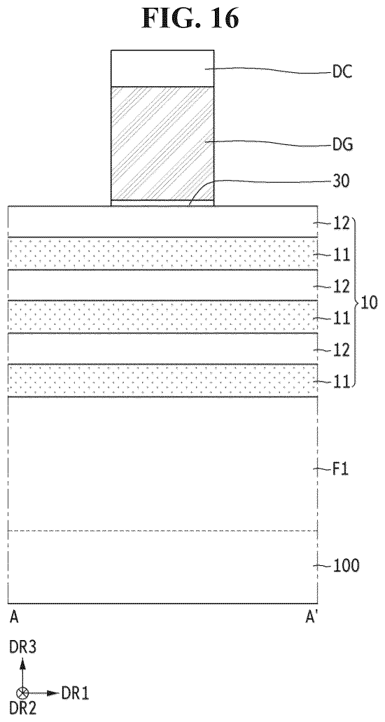

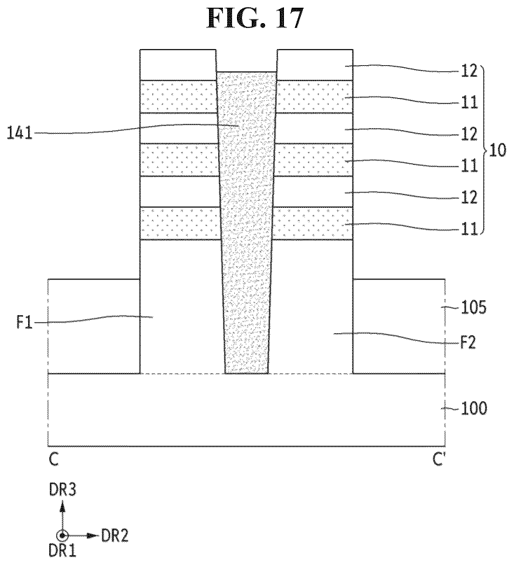

Referring to FIGS. 16 and 17, the remaining portion of the pad oxide layer 30 may be etched, except for the portion overlapping with the dummy gate DG in the vertical direction DR3. While the pad oxide layer 30 is being etched, a portion of the isolation material layer 141M (see FIG. 15) in the region where the dummy gate DG is not formed may be etched. After this etching process is completed, the remaining isolation material layer 141M (see FIG. 15) may be defined as the first portion 141 of the channel isolation layer 140 (see FIGS. 3 and 4). For example, in the portion where the dummy gate DG is not formed, the upper surface of the first portion 141 of the channel isolation layer 140 (see FIGS. 3 and 4) may be formed lower than the upper surface of the stacked structure 10.

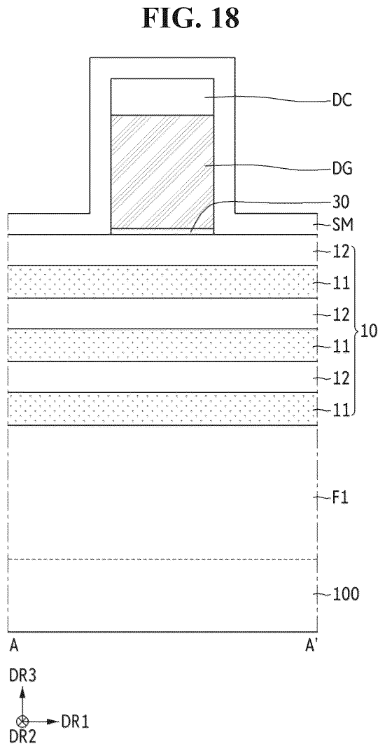

Referring to FIGS. 18 to 21, a spacer material layer SM may be formed to cover the exposed surface of each of the dummy gate DG, dummy capping pattern DC, stacked structure 10, field insulating layer 105, and first portion 141 of the channel isolation layer 140 (see FIGS. 3 and 4). For example, the spacer material layer SM may be conformally formed. For example, the spacer material layer SM may include the same material as the gate spacer 111 (see FIG. 2).

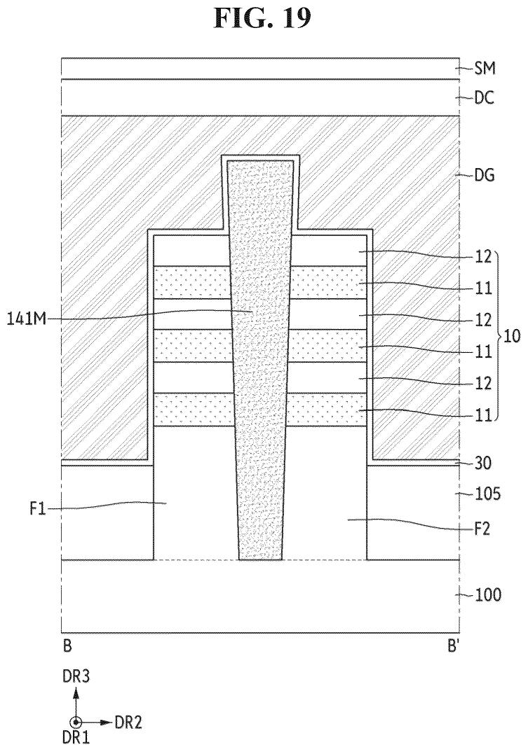

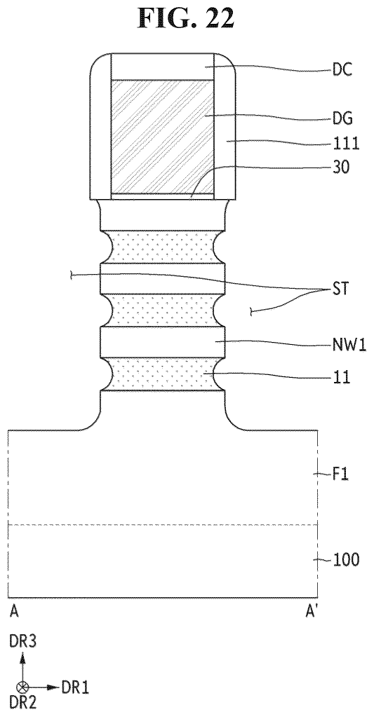

Referring to FIGS. 22 to 24, the stacked structure 10 (see FIGS. 18 to 20) may be etched to form a source/drain trench ST using the dummy capping pattern DC and the dummy gate DG as masks. For example, the source/drain trench ST may be formed on both sides of dummy gates DG on the first active pattern F1. In addition, the source/drain trench ST may be formed on both sides of the dummy gate DG on the second active pattern F2. For example, after the source/drain trench ST is formed, the spacer material layer SM (see FIG. 18) remaining on both sidewalls of the dummy gate DG may be defined as a gate spacer 111. For example, after a source/drain trench ST is formed, the second semiconductor layer 12 (see FIGS. 18 and 19) remaining on the first active pattern F1 may be defined as the first plurality of nanosheets NW1, and the second semiconductor layer 12 (see FIG. 19) remaining on the second active pattern F2 may be defined as the second plurality of nanosheets NW2 (see FIG. 3).

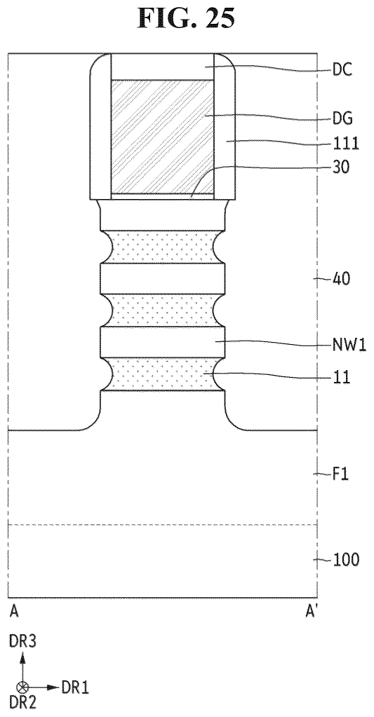

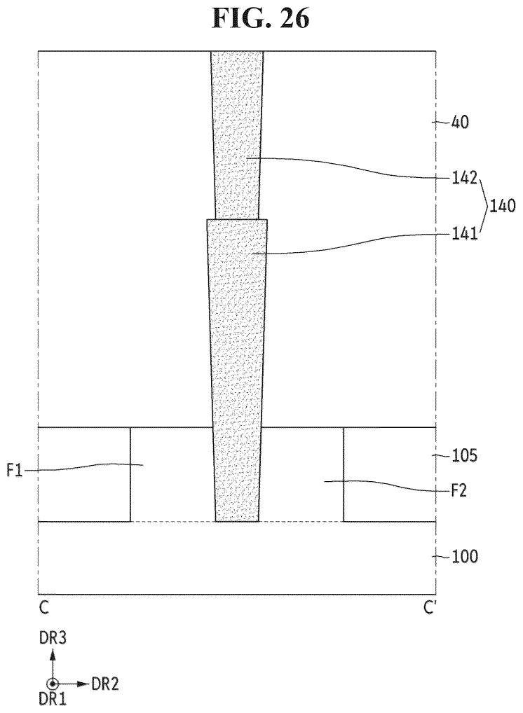

Referring to FIGS. 25 and 26, a protective layer 40 may be formed to fill the source/drain trench ST (see FIG. 22). For example, the protective layer 40 may surround the sidewalls of each of the gate spacer 111 and the first portion 141 of the channel isolation layer 140. For example, the protective layer 40 may cover the upper surface of the first portion 141 of the channel isolation layer 140. For example, the upper surface of the protective layer 40 may be formed on the same plane as the upper surface of the dummy capping pattern DC. For example, the protective layer 40 may include SOH (Spin-On Hardmask). Subsequently, a second portion 142 of the channel isolation layer 140 may be formed by penetrating the protective layer 40 in the vertical direction DR3 to connect to the upper surface of the first portion 141 of the channel isolation layer 140.

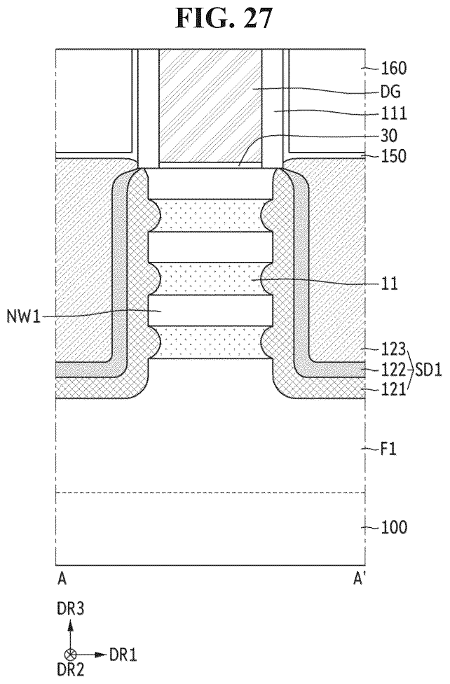

Referring to FIGS. 27 to 29, the protective layer 40 (see FIGS. 25 and 26) may be etched away. Subsequently, the first source/drain region SD1 may be formed inside the source/drain trench ST on the first active pattern F1. The second source/drain region SD2 may be formed on the second active pattern F2. For example, the first liner layer 121 of the first source/drain region SD1 may be conformally formed on the upper surface of the first active pattern F1 and on the first sidewall of the channel isolation layer 140 in the second horizontal direction DR2. The first liner layer 131 of the second source/drain region SD2 may be conformally formed on the upper surface of the second active pattern F2 and on the second sidewall of the channel isolation layer 140 in the second horizontal direction DR2.

Subsequently, the second liner layer 122 of the first source/drain region SD1 and the filling layer 123 of the first source/drain region SD1 may be sequentially formed on the first liner layer 121 of the first source/drain region SD1. The second liner layer 132 of the second source/drain region SD2 and the filling layer 133 of the second source/drain region SD2 may be sequentially formed on the first liner layer 131 of the second source/drain region SD2. As a result, the first and second source/drain regions SD1, SD2 may be formed. Then, the etching stop layer 150 and the interlayer insulating layer 160 may be sequentially formed. Next, a planarization process may be performed to expose the upper surface of the dummy gate DG.

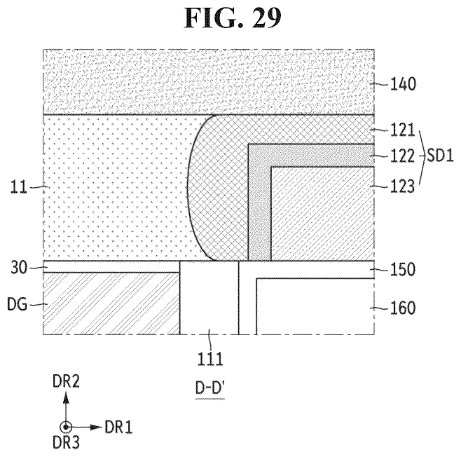

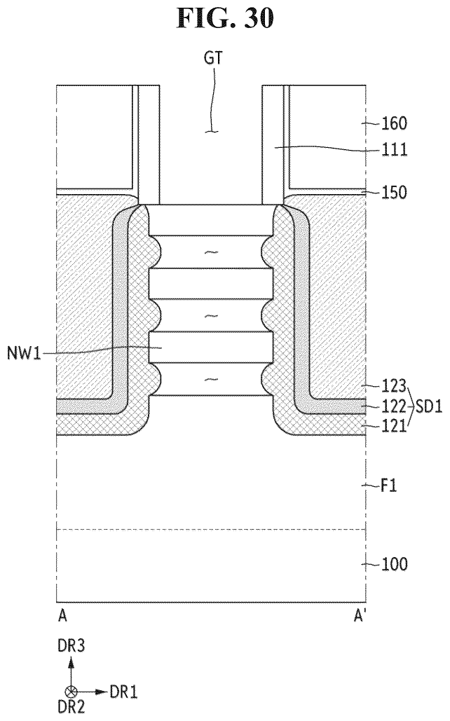

Referring to FIGS. 30 to 32, the dummy gate DG (see FIGS. 27 and 29), the pad oxide layer 30 (see FIGS. 27 and 29), and the first semiconductor layer 11 (see FIGS. 27 and 29) may be etched. The regions where the dummy gate DG (see FIGS. 27 and 29), the pad oxide layer (see in FIGS. 27 and 29), and the first semiconductor layer 11 (see FIGS. 27 and 29) are etched may be defined as the gate trench GT.

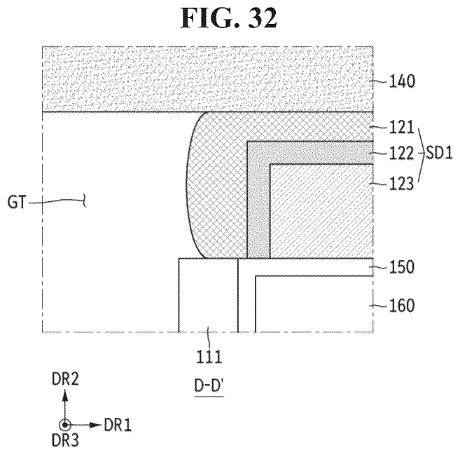

Referring to FIGS. 2 to 5, the gate insulating layer 112, the gate electrode G1, and the capping pattern 113 may be sequentially formed inside the gate trench GT (see FIGS. 30 and 32). Subsequently, the first source/drain contact CA1 may be formed by penetrating the interlayer insulating layer 160 and the etching stop layer 150 in the vertical direction DR3 to connect to the first source/drain region SD1. The second source/drain contact CA2 may be formed by penetrating the interlayer insulating layer 160 and the etching stop layer 150 in the vertical direction DR3 to connect to the second source/drain region SD2. The silicide layer SL may be formed at the interface between the first source/drain region SD1 and the first source/drain contact CA1 and at the interface between the second source/drain region SD2 and the second source/drain contact CA2. Through the fabrication process, the semiconductor device shown in FIGS. 2 to 5 may be fabricated.

The semiconductor device according to some exemplary embodiments fabricated by the method described above may include the first source/drain region SD1 with a first liner layer 121, a second liner layer 122, and a filling layer 123. Referring to FIG. 29, the first liner layer 121 and the second liner layer 122 may each be formed between the first semiconductor layer 11 and the filling layer 123. As a result, in the semiconductor device according to various exemplary embodiments, the thickness between the first semiconductor layer 11 and the filling layer 123 may be reinforced in the region adjacent to the gate spacer 111. The first liner layer 121 and the second liner layer 122 may each be formed between the channel isolation layer 140 and the filling layer 123. As a result, in the semiconductor device according to various exemplary embodiments, the thickness between the first semiconductor layer 11 and the filling layer 123 may be reinforced in the region adjacent to the channel isolation layer 140.

The semiconductor device according to some exemplary embodiments fabricated by the method described above and the method for fabricating the semiconductor device according to some exemplary embodiments described above may reinforce the thickness between the first semiconductor layer 11 and the filling layer 123 containing high-concentration germanium (Ge) in regions adjacent to each of the gate spacer 111 and the channel isolation layer 140. As a result, this reinforcement may prevent damage to the filling layer 123 in subsequent processes where the first semiconductor layer 11 is etched, thereby improving the reliability of the source/drain region SD1.

If the filling layer 123 is grown directly from the surface of the channel isolation layer 140, defects in the crystallinity of the filling layer 123 may occur. The method for fabricating a semiconductor device according to some exemplary embodiments may include forming the first liner layer 121 and the second liner layer 122 on the surface of the channel isolation layer 140. This formation allows the crystallinity of the filling layer 123 to be improved by growing the filling layer 123 from the surface of the second liner layer 122, thereby improving the reliability of the source/drain region SD1.

In the semiconductor device according to some exemplary embodiments fabricated by the above-described method, the source/drain region SD1 may include the first liner layer 121, the second liner layer 122, and the filling layer 123, wherein the first liner layer 121 may be formed conformally along the upper surface of the active pattern F1 and the sidewall of the channel isolation layer 140. The filling layer 123 is not in contact with either the upper surface of the active pattern F1 or the sidewall of the channel isolation layer 140.

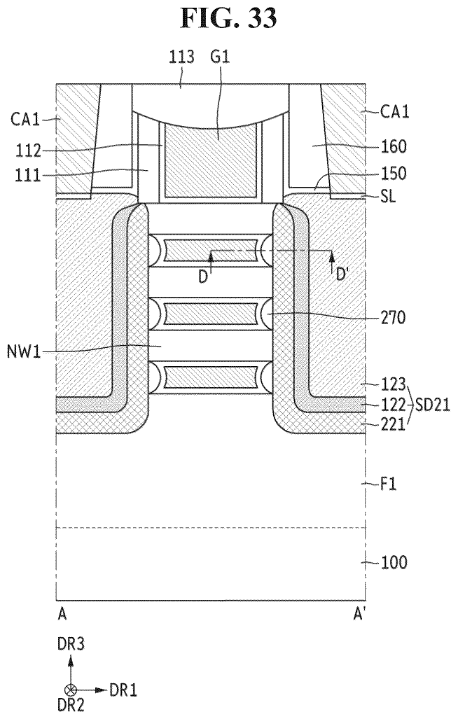

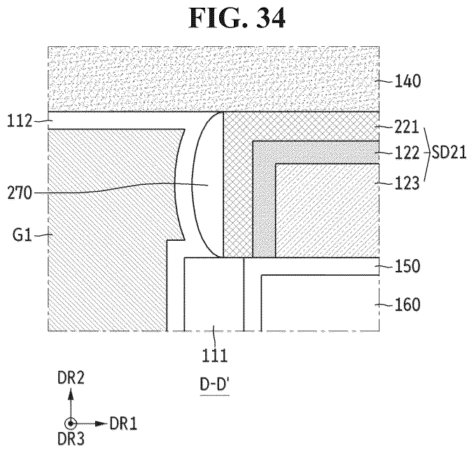

A semiconductor device according to some exemplary embodiments is described with reference to FIGS. 33 and 34. The description will focus on the differences from the semiconductor device shown in FIGS. 1 to 5.

FIG. 33 is a cross-sectional view for explaining a semiconductor device according to some exemplary embodiments. FIG. 34 is a plan view taken along line D-D′ of FIG. 33.

Referring to FIG. 33 and FIG. 34, in the semiconductor device, an inner spacer 270 may be disposed between the gate electrodes G1 and the first source/drain region SD21.

In some exemplary embodiments, the inner spacer 270 may be disposed between the gate insulating layer 112 and the first liner layer 221 of the first source/drain region SD21 in the region between the upper surface of the first active pattern F1 and the bottom surface of the lowermost nanosheet of the first plurality of nanosheets NW1. In some exemplary embodiments, the inner spacer 270 may be disposed between the gate insulating layer 112 and the first liner layer 221 of the first source/drain region SD21 in the region between adjacent first plurality of nanosheets NW1. The inner spacer 270 may be in contact with each of the gate insulating layer 112 and the first liner layer 221. In some exemplary embodiments, the inner spacer 270 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), or silicon oxycarbide (SiOC), or a combination thereof.

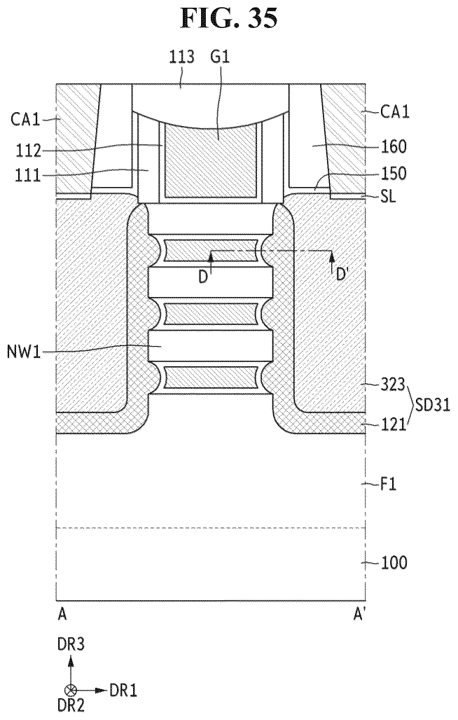

Hereinafter, a semiconductor device according to some exemplary embodiments is described with reference to FIGS. 35 to 37. The description focuses on the differences from the semiconductor device shown in FIGS. 1 to 5.

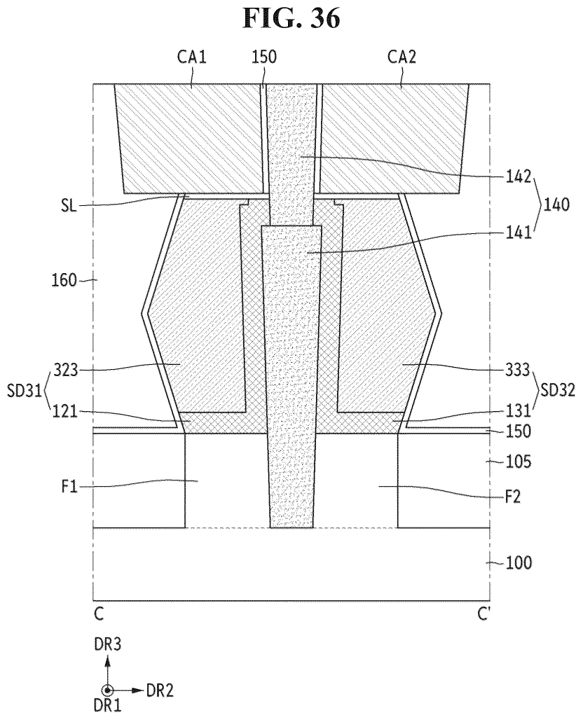

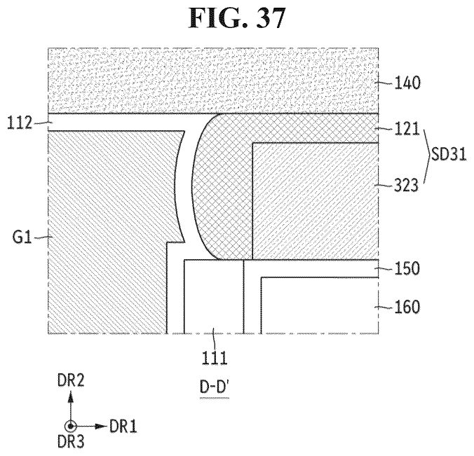

FIGS. 35 and 36 are cross-sectional views for explaining semiconductor devices according to some exemplary embodiments. FIG. 37 is a plan view taken along line D-D′ of FIG. 35.

Referring to FIGS. 35 to 37, in the semiconductor device, the first source/drain region SD31 and the second source/drain region SD32 may each be formed as a double layer.

In some exemplary embodiments, the first source/drain region SD31 may include the first liner layer 121 and the filling layer 323. In some exemplary embodiments, the second source/drain region SD32 may include the first liner layer 131 and the filling layer 333. For example, the first liner layer 121 of the first source/drain region SD31 and the first liner layer 131 of the second source/drain region SD32 may each be formed as a single layer. In other words, as compared to the exemplary embodiments described with respect to FIGS. 1-5, the semiconductor device described with respect to FIGS. 35-37 may omit the second liner layer 122 and the second liner layer 132.

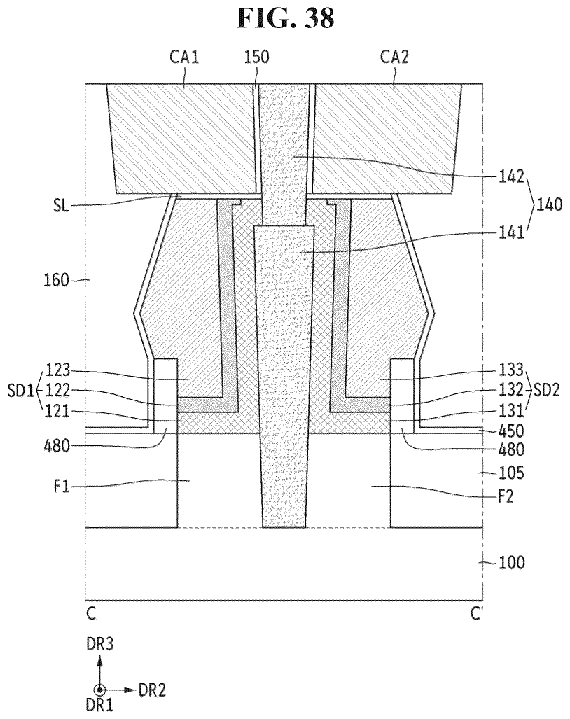

Hereinafter, a semiconductor device according to some exemplary embodiments is described with reference to FIG. 38. The description focuses on the differences from the semiconductor device shown in FIGS. 1 to 5.

FIG. 38 is a cross-sectional view for explaining the semiconductor device according to some exemplary embodiments.

Referring to FIG. 38, in the semiconductor, a source/drain spacer 480 may be disposed on the sidewall of each of the first and second source/drain regions SD1, SD2 in the second horizontal direction DR2.

In some exemplary embodiments, the source/drain spacer 480 may be in contact with the upper surface of the field insulating layer 105. The source/drain spacer 480 may be disposed between the etching stop layer 450 and the sidewall of the first source/drain region SD1 in the second horizontal direction DR2. That is, at least a portion of the first source/drain region SD1 may be disposed between the source/drain spacer 480 and the first sidewall of the channel isolation layer 140 in the second horizontal direction DR2. In some exemplary embodiments, the source/drain spacer 480 may be disposed between the etching stop layer 450 and the sidewall of the second source/drain region SD2 in the second horizontal direction DR2. In other words, at least a portion of the second source/drain region SD2 may be disposed between the source/drain spacer 480 and the second sidewall of the channel isolation layer 140 in the second horizontal direction DR2.

In some exemplary embodiments, each of the first liner layer 121 and the second liner layer 122 of the first source/drain region SD1 may be in contact with the sidewall of the source/drain spacer 480 in the second horizontal direction DR2. In some exemplary embodiments, the first liner layer 131 and the second liner layer 132 of the second source/drain region SD2 may each be in contact with the sidewall of the source/drain spacer 480 in the second horizontal direction DR2. In some exemplary embodiments, the source/drain spacer 480 may overlap with the filling layer 123 of the first source/drain region SD1 and the filling layer 133 of the second source/drain region SD2 in the vertical direction DR3.

In some exemplary embodiments, the upper surface of the source/drain spacer 480 may be formed lower than the upper surface of each of the first and second source/drain regions SD1, SD2. In some exemplary embodiments, the source/drain spacer 480 may include at least one of silicon nitride (SiN), silicon oxynitride (SiON), silicon oxide (SiO₂), silicon carbonitride (SiCN), silicon oxycarbonitride (SiOCN), silicon boronitride (SiBN), silicon oxyboronitride (SiOBN), silicon borocarbide (SiBC), silicon boron carbonitride (SiBCN), or silicon oxycarbide (SiOC), or combinations thereof.

In some exemplary embodiments, the interlayer insulating layer 160 may cover the source/drain spacer 480, and each of the first and second source/drain regions SD1, SD2. The etching stop layer 150 may be disposed between the source/drain spacer 480, each of the first and second source/drain regions SD1, SD2, and the interlayer insulating layer 160. The etching stop layer 150 may be in contact with the source/drain spacer 480.

While exemplary embodiments have been described above with reference to the accompanying drawings, it will be understood that exemplary embodiments are not limited to the above described embodiments and may be fabricated in a variety of different forms, and those of ordinary skill in the art to which the present disclosure belongs may recognize that various exemplary embodiments may be implemented in other specific forms without changing the technical idea or essential features of the present disclosure. Therefore, all such modifications and forms will be understood to be included within the scope of the appended claims.

What is claimed is:

1. A semiconductor device comprising:
a substrate;
a first active pattern extending in a first horizontal direction on the substrate;
a second active pattern extending in the first horizontal direction on the substrate, the second active pattern spaced apart from the first active pattern in a second horizontal direction different from the first horizontal direction;
a first plurality of nanosheets stacked and spaced apart from each other in a vertical direction on the first active pattern;
a second plurality of nanosheets stacked and spaced apart from each other in the vertical direction on the second active pattern and spaced apart from the first plurality of nanosheets in the second horizontal direction;
a channel isolation layer extending in the first horizontal direction between the first active pattern and the second active pattern, the channel isolation layer comprising a first sidewall in the second horizontal direction and a second sidewall opposite the first sidewall in the second horizontal direction, the first sidewall of the channel isolation layer being in contact with the first active pattern and each of the first plurality of nanosheets, the second sidewall of the channel isolation layer being in contact with the second active pattern and each of the second plurality of nanosheets;
a first source/drain region in contact with the first sidewall of the channel isolation layer on the first active pattern; and
a second source/drain region in contact with the second sidewall of the channel isolation layer on the second active pattern,
wherein the first source/drain region comprises:
a liner layer that is conformal and is in contact with an upper surface of the first active pattern, the first sidewall of the channel isolation layer, and sidewalls of the first plurality of nanosheets in the first horizontal direction; and
a filling layer disposed on the liner layer, the filling layer not being in contact with the first sidewall of the channel isolation layer.

2. The semiconductor device of claim 1, wherein each of the filling layer and the liner layer includes germanium, and
wherein a concentration of germanium contained in the filling layer is greater than a concentration of germanium contained in the liner layer.

3. The semiconductor device of claim 1, further comprising:
a gate electrode extending in the second horizontal direction on the first active pattern and the second active pattern, the gate electrode surrounding each of the first plurality of nanosheets and each of the second plurality of nanosheets.

4. The semiconductor device of claim 3, wherein the channel isolation layer isolates the gate electrode in the second horizontal direction.

5. The semiconductor device of claim 3, further comprising:
an inner spacer that is in contact with the liner layer and is disposed between the first source/drain region and the gate electrode between adjacent ones of the first plurality of nanosheets.

6. The semiconductor device of claim 1, further comprising:
a source/drain contact disposed on an upper surface of the first source/drain region, the source/drain contact electrically connected to the first source/drain region; and
a silicide layer disposed along an interface between the first source/drain region and the source/drain contact,
wherein the silicide layer is in contact with the liner layer and the filling layer.

7. The semiconductor device of claim 1, wherein an uppermost surface of the channel isolation layer is higher than an upper surface of an uppermost nanosheet of the first plurality of nanosheets.

8. The semiconductor device of claim 1, wherein the liner layer comprises:
a first liner layer that is conformal and is in contact with the upper surface of the first active pattern, the first sidewall of the channel isolation layer, and the sidewalls of the first plurality of nanosheets in the first horizontal direction; and
a second liner layer that is conformal and is disposed between the first liner layer and the filling layer.

9. The semiconductor device of claim 8, wherein each of the first liner layer and the second liner layer includes germanium, and
wherein a concentration of germanium contained in the second liner layer is greater than a concentration of germanium contained in the first liner layer.

10. The semiconductor device of claim 8, wherein the second liner layer is not in contact with the first sidewall of the channel isolation layer.

11. The semiconductor device of claim 1, wherein the liner layer is a single layer.

12. The semiconductor device of claim 1, further comprising:
a source/drain spacer disposed on a sidewall of the first source/drain region in the second horizontal direction and overlapping with the filling layer in the vertical direction, a sidewall of the source/drain spacer in the second horizontal direction being in contact with the liner layer;
an interlayer insulating layer covering the first source/drain region and the source/drain spacer; and
an etching stop layer that is conformal and is disposed between the first source/drain region and the interlayer insulating layer and between the source/drain spacer and the interlayer insulating layer.

13. A semiconductor device comprising:
a substrate;
a first active pattern extending in a first horizontal direction on the substrate;
a second active pattern extending in the first horizontal direction on the substrate, the second active pattern spaced apart from the first active pattern in a second horizontal direction different from the first horizontal direction;
a channel isolation layer extending in the first horizontal direction between the first active pattern and the second active pattern, sidewalls of the channel isolation layer in the second horizontal direction being in contact with the first active pattern and the second active pattern;
a gate electrode extending in the second horizontal direction on the first active pattern and the second active pattern; and
a source/drain region disposed on one side of the gate electrode on the first active pattern,
wherein the source/drain region comprises:
a first liner layer that is conformal and is in contact with an upper surface of the first active pattern and a sidewall of the sidewalls of the channel isolation layer in the second horizontal direction;
a second liner layer that is formed conformally and is disposed on the first liner layer, the second liner layer being in contact with the first liner layer and being not in contact with the sidewall of the sidewalls of the channel isolation layer in the second horizontal direction; and
a filling layer disposed on the second liner layer, the filling layer being in contact with the second liner layer and being not in contact with the sidewall of the sidewalls of the channel isolation layer in the second horizontal direction.

14. The semiconductor device of claim 13, wherein each of the first liner layer, the second liner layer, and the filling layer includes germanium,
wherein a concentration of germanium contained in the second liner layer is greater than a concentration of germanium contained in the first liner layer, and
wherein a concentration of germanium contained in the filling layer is greater than the concentration of germanium contained in the second liner layer.

15. The semiconductor device of claim 13, further comprising:
a first plurality of nanosheets stacked and spaced apart from each other in a vertical direction on the first active pattern, the first plurality of nanosheets being surrounded by the gate electrode; and
a second plurality of nanosheets stacked and spaced apart from each other in the vertical direction on the second active pattern, the second plurality of nanosheets being surrounded by the gate electrode and spaced apart from the first plurality of nanosheets in the second horizontal direction,
wherein an uppermost surface of the channel isolation layer is higher than an upper surface of an uppermost nanosheet of the first plurality of nanosheets.

16. The semiconductor device of claim 15, wherein the first plurality of nanosheets are in contact with a first sidewall of the sidewalls of the channel isolation layer in the second horizontal direction and the second plurality of nanosheets are in contact with a second sidewall of the sidewalls of the channel isolation layer in the second horizontal direction.

17. The semiconductor device of claim 13, further comprising:
a source/drain contact disposed on an upper surface of the source/drain region, the source/drain contact electrically connected to the source/drain region; and
a silicide layer disposed along an interface between the source/drain region and the source/drain contact,
wherein the silicide layer is in contact with each of the first liner layer, the second liner layer and the filling layer.

18. The semiconductor device of claim 13, wherein an uppermost surface of the channel isolation layer is higher than an upper surface of the source/drain region.

19. The semiconductor device of claim 13, further comprising:
a source/drain spacer disposed on a sidewall of the source/drain region in the second horizontal direction and overlapping with the filling layer in a vertical direction, a sidewall of the source/drain spacer in the second horizontal direction being in contact with the first liner layer and the second liner layer;
an interlayer insulating layer covering the source/drain region and the source/drain spacer; and
an etching stop layer that is conformal and is disposed between the interlayer insulating layer and the source/drain region and between the interlayer insulating layer the source/drain spacer.

20. A semiconductor device comprising:
a substrate;
a first active pattern extending in a first horizontal direction on the substrate;
a second active pattern extending in the first horizontal direction on the substrate and being spaced apart from the first active pattern in a second horizontal direction different from the first horizontal direction;
a first plurality of nanosheets stacked and spaced apart from each other in a vertical direction on the first active pattern;
a second plurality of nanosheets stacked and spaced apart from each other in the vertical direction on the second active pattern and being spaced apart from the first plurality of nanosheets in the second horizontal direction;
a channel isolation layer extending in the first horizontal direction between the first active pattern and the second active pattern, the channel isolation layer comprising a first sidewall in the second horizontal direction and a second sidewall opposite the first sidewall in the second horizontal direction, the first sidewall of the channel isolation layer being in contact with the first active pattern and each of the first plurality of nanosheets, the second sidewall of the channel isolation layer being in contact with the second active pattern and each of the second plurality of nanosheets;
a gate electrode extending in the second horizontal direction on the first active pattern and the second active pattern, the gate electrode surrounding each of the first plurality of nanosheets and each of the second plurality of nanosheets and being isolated in the second horizontal direction by the channel isolation layer;
a first source/drain region disposed on one side of the gate electrode on the first active pattern, the first source/drain region being in contact with the first sidewall of the channel isolation layer;
a second source/drain region disposed on the one side of the gate electrode on the second active pattern, the second source/drain region being in contact with the second sidewall of the channel isolation layer;
a source/drain contact disposed on an upper surface of the first source/drain region and being electrically connected to the first source/drain region; and
a silicide layer disposed along an interface between the first source/drain region and the source/drain contact,
wherein the first source/drain region comprises:
a first liner layer that is conformal and is in contact with an upper surface of the first active pattern, the first sidewall of the channel isolation layer, and sidewalls of the first plurality of nanosheets in the first horizontal direction;
a second liner layer that is conformal and is disposed on the first liner layer, the second liner layer being in contact with the first liner layer and being not in contact with the first sidewall of the channel isolation layer; and
a filling layer disposed on the second liner layer, the filling layer being in contact with the second liner layer and being not in contact with the first sidewall of the channel isolation layer,
wherein the silicide layer is in contact with each of the first liner layer, the second liner layer and the filling layer.
